(19) United States
(12) Patent Application Publication
(10) Pub. No.: US 2011/0134513 A1
(43) Pub. Date: Jun. 9, 2011

(54) OPTICAL DEVICE MODULE

(75) Inventors: Dong Churl Kim, Daejeon (KR); Byung-seok Choi, Daejeon (KR); Hyun Soo Kim, Daejeon (KR); Kisoo Kim, Daejeon (KR); O-Kyun Kwon, Daejeon (KR); Dae Kon Oh, Daejeon (KR)

(73) Assignee: ELECTRONICS AND TELECOMMUNICATIONS RESEARCH INSTITUTE, Daejeon (KR)

(21) Appl. No.: 12/773,196

(22) Filed: May 4, 2010

(30) Foreign Application Priority Data
Dec. 7, 2009 (KR) 10-2009-0120617

(51) Int. Cl. H01S 5/026; G02B 6/26; G02B 6/42

(52) U.S. Cl. 359/344; 385/28

(57) ABSTRACT

Provided is an optical device module that can improve miniaturization and integration. The optical device module includes a semiconductor optical amplifier having a buried structure and including a first active layer buried in a clad layer disposed on a first substrate, an optical modulator in which a sidewall of a second active layer disposed in a direction of the first active layer on a second substrate junctioned to the first substrate is exposed, the optical modulator having a ridge structure, and at least one multi-mode interference coupler in which the second active layer junctioned to the first active layer is buried in the clad layer, the multi-mode interference coupler sharing the second active layer on the second substrate between the optical modulator and the semiconductor optical amplifier and integrated with the second optical device.

### CROSS-REFERENCE TO RELATED APPLICATIONS

This U.S. non-provisional patent application claims priority under 35 U.S.C. §119 of Korean Patent Application No. 10-2009-0120617, filed on Dec. 7, 2009, the entire contents of which are hereby incorporated by reference.

### BACKGROUND OF THE INVENTION

The present invention disclosed herein relates to an optical device module, and more particularly, to an optical device module in which optical devices including active layers having structures different from each other are junctioned to each other.

As semiconductor lasers and optical fibers are developed, high-speed optical communication such as internet communication can be realized. Researches with respect to semiconductor optical devices were actively conducted in the past in a way that couples a plurality of single optical devices to each other. With the tendency of the miniaturization of optical devices, integration technologies of the device are emerging as a major issue lately. However, it is not easy to integrate two or more kinds of optical devices having three-dimensional shapes or optical control operations different from each other.

### SUMMARY OF THE INVENTION

The present invention provides an optical device module in which two or more kinds of optical devices having three-dimensional shapes or optical control operations different from each other are easily integrated to each other.

Embodiments of the present invention provide optical device modules including: a first substrate; at least one first optical device in which a first active layer through which light passes is buried in a clad layer on the first substrate; a second substrate junctioned to the first substrate including the first optical device; at least one second optical device in which a sidewall of a second active layer disposed on the second substrate is exposed from the clad layer; and a multi-mode interference coupler comprising the second active layer disposed on the second substrate between the second optical device and the first optical device, wherein the multi-mode interference coupler is junctioned to the first optical device and integrated with the second optical device and buried in the clad layer.

In some embodiments, the multi-mode interference coupler may include at least one input part in which the second active layer having a first width equal to that of the first active layer is junctioned to the first active layer, an interference part connected to the input part and having a second width greater than that of the first width, and at least one output part connected to the interference part facing the input part and having a third width less than that of the second width.

In other embodiments, the multi-mode interference coupler may include at least one mode adaptor disposed at the input part or the output part.

In still other embodiments, the first width of the input part may be less than the third width of the output part.

In even other embodiments, the second optical device may include an optical modulator including the second active layer having the third width and a second electrode disposed on an upper portion of the clad layer on the second active layer.

In yet other embodiments, sidewalls of the second active layer and the clad layer of the optical modulator may be passivated with polyimide.

In further embodiments, the second optical device may have a deep ridge structure or a deep ridge that is passivated with polyimide.

In still further embodiments, the first optical device may include a semiconductor optical amplifier including the first active layer having the first, current blocking layers disposed on both sides of the first active layer, and a first electrode having a fourth width greater than the first width.

In even further embodiments, the semiconductor optical amplifier may have a planar buried heterostructure or a buried ridge structure.

In yet further embodiments, the first active layer of the first optical device and the second active layer of the multi-mode interference coupler may be butt-jointed to each other.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a perspective view of an optical device module according to an embodiment of the present invention;

FIG. 2 is a plan view taken along line I-I′ of FIG. 1;

FIG. 3 is a graph illustrating a variation of transmission according to a width variation of an interference part of a multi-mode interference coupler of a mode adaptor;

FIG. 4 is a view illustrating a result obtained by calculating an intensity of an optical signal passing through an optical device module according to an embodiment of the present invention; and

FIGS. 5 and 6 are plan views of an optical device module according to another embodiment of the present invention.

### DETAILED DESCRIPTION OF PREFERRED EMBODIMENTS

Objects, other objects, characteristics and advantages of the present invention will be easily understood from an explanation of a preferred embodiment that will be described in detail below by reference to the attached drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the specification, it will be understood that when a layer (or film) is referred to as being ‘on’ another layer or substrate, it can be directly on the other layer or substrate, or intervening layers may also be present. Also, in the figures, the dimensions of layers and regions are exaggerated for clarity of illustration. Also, though terms like a first, a second, and a third are used to describe various regions and layers in various embodiments of the present invention, the regions and the layers are not limited to these terms. These terms are used only to discriminate one region or layer from another region or layer. Therefore, a layer referred to as a first layer in one embodiment can be referred to as a second layer in another embodiment. An embodiment described and exemplified herein includes a complementary embodiment thereof.

Hereinafter, an optical device module according to an embodiment of the present invention will be described with reference to accompanying drawings.

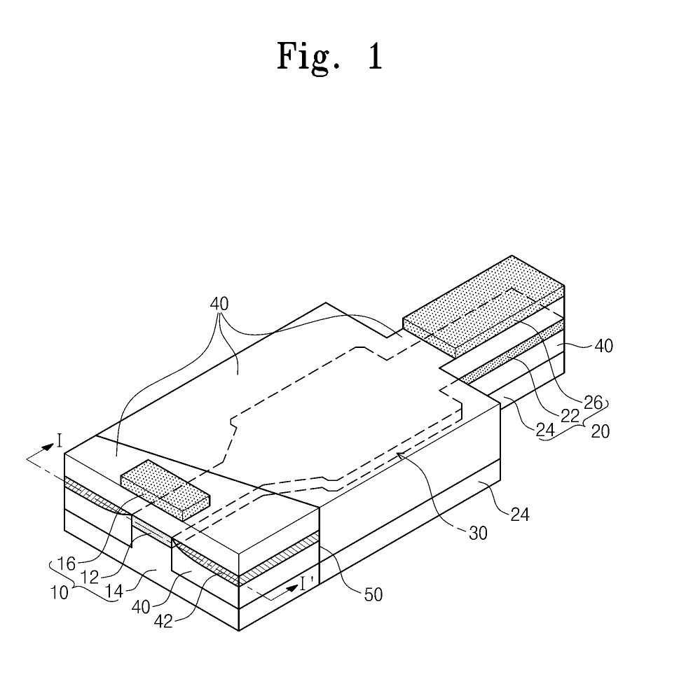

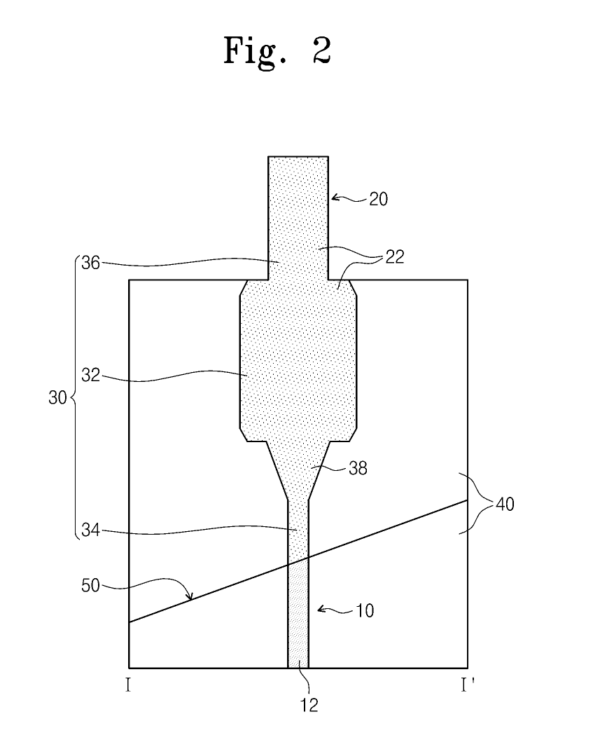

FIG. 1 is a perspective view of an optical device module according to an embodiment of the present invention, and FIG. 2 is a plan view taken along line I-I′ of FIG. 1.

Referring to FIG. 1, an optical device module according to an embodiment may include a semiconductor optic amplifier (SOA) 10 in which a first active layer 12 is buried in a clad layer 40 and an optic modulator (OM) 20 in which a sidewall of a second active layer 22 is exposed from the clad layer 40. In addition, the optical device module may further include a multi-mode interference (MMI) coupler 30. The MMI coupler 30 is disposed between the OM 20 and the SOA 10 and junctioned to the SOA 10. Also, in the MMI coupler 30, the second active layer 22 buried in the clad layer 40 is integrated with the OM 20. The MMI coupler 30 is formed one body of the OM 20.

Here, the OM 20 shares the second active layer 22 with the MMI coupler 30. Also, the OM 20 may be integrated with the MMI coupler 30 through an etch process by which the clad layer 40 adjacent to a second electrode 26 and the second active layer 22 and a second substrate 24 are removed.

Thus, in the optical device module according to an embodiment, the MMI coupler 30 and the OM 20 may be integrated with each other to improve miniaturization and integration of an optical device.

The first active layer 12 and the second active layer 22 may constitute a core layer. The SOA 10 and the MMI coupler 30 are connected to a junction surface 50 junctioned using a butt joint. The SOA 10 may have a buried structure in which the first active layer 12 is covered by the clad layer 40. Similarly, the MMI coupler 30 may have a buried structure in which the second active layer 22 is covered by the clad layer 40. Since the SOA 10 and the MMI coupler 30 have the buried structures, they may be easily junctioned to each other. That is, the MMI coupler 30 may have the same buried structure as the SOA 10 so that the first active layer 12 is junctioned to the second active layer 22.

Thus, in the optical device module according to an embodiment of the present invention, the OM 20 and the MMI coupler 30, which share the second active layer 22 with each other are integrated. Also, the SOA 10 and the MMI coupler 30 that include the first active layer 12 and the second active layer 22, which are different from each other, may be junctioned to each other to realize the miniaturization of the optical device.

The SOA 10 may be a first optical device amplifying an optical signal applied through the first active layer 12. In the SOA 10, a forward voltage may be vertically applied to the first active layer 12 between a first substrate 14 and a first electrode 16 to inject current. Also, when an optical signal is incident to the first active layer 12 in a direction parallel to that in which the MMI coupler 30 is junctioned, the SOA 10 may amplify an intensity of the optical signal. The first active layer 12 may amplify the intensity of the optical signal in proportion to an intensity of current flowing between the first substrate 14 and the first electrode 16.

For example, the first active layer 12 may include an intrinsic InGaAsP semiconductor having an energy band gap of about 0.8 eV (1.55 μm). Also, the first active layer 12 may have a thickness of about 0.3 μm to about 0.5 μm and a width of about 1 μm. The first electrode 16 may include a conductive metal formed of Ti/Pt/Au. Also, the first electrode 16 may have a width of about 3 μm greater than that of the first active layer 12. The first substrate 14 may be formed of N-type InP, and the clad layer 40 may be formed of P-type InP. A current blocking layer 42 disposed adjacent to the first active layer 12 may be formed of N-type InP. That is, the clad layer 40 and the current blocking layer 42, which are adjacent to the first active layer 12, may have a PNP structure to concentrate current into the first active layer 12. Although not shown, a ground electrode formed of a conductive metal or a ground substrate formed of N-type InP may be further disposed on a bottom surface of the first substrate facing the first electrode 16.

Thus, the SOA 10 may have a planar buried heterostructure (PBH) which has the current blocking layer 42 around the first active layer 12 buried between the first substrate 14 and the clad layer 40 or a buried ridge structure (BRS).

The OM 20 may be a second optical device that transfer an electrical signal applied from the outside to an light. Thus, the OM 20 may modulate the optical signal transmitted to the second active layer 22 according to a signal voltage applied between the second substrate 24 and the second electrode 26.

Both lateral surfaces of the OM 20 may be filled with polyimide, and the OM 20 is passivated to improve reliability of the optical device. Also, an entire surface of the OM 20 may be planarized to easily manufacture the second electrode 22. Here, the second electrode 22 may have a width greater than that of the OM 20.

For example, the second active layer 22 of the OM 20 may have a stacked structure having a width of about 2.5 μm to about 3.0 μm. The second active layer 22 include an intrinsic InGaAsP semiconductor having an energy band gap of about 0.85 eV (1.46 μm). Similarly, the clad layer 40 and the second substrate 24 may be formed of N-type InP. Although not shown, a ground electrode formed of a conductive metal may be disposed on a bottom surface of the second substrate 24.

The second active layer 22 may serve as an optical waveguide disposed between the second substrate 24 and the clad layer 40. Also, a sidewall of the second active layer 22 may contact a material having a significantly low refractive index to maximally confine light passing through the inside of the second active layer 22 within the second active layer 22. Thus, the OM 20 may have a deep ridge structure in which the sidewall of the second active layer 22 is exposed to air having a refractive index of 1.0. In addition, the sidewall of the second active layer 22 is be planarized as a polyimide layer having a refractive index less than that of InP to maximally confine light within the second active layer 22, and simultaneously, the OM 20 is passivated to improve the reliability of the device.

At this time, an etch process may be performed at once to remove the clad layer 40 and the second substrate 24, which are adjacent to the second active layer 22, thereby form the OM 20 having the deep ridge structure. That is, the OM 20 may have a ridge structure in which the polyimide layer is buried into a sidewall of the second active layer 22 having the deep ridge structure. The second optical device having the deep ridge structure, which is passivated with the polyimide, may include an optical waveguide.

The MMI coupler 30 may be generally used for dividing one optical waveguide into a plurality of optical waveguides or connect a plurality of optical waveguides to each other. The MMI coupler 30 may include an interference part 32 having a rectangular shape, an input part 34 and an output part 36. The input part 34 and the output part 36 may be respectively disposed on both ends of the interference part 32. An edge of the interference part 32 may be tapered. Also, the interference part 32 may use a total internal reflection of light to interfere with an optical signal. The interference part 32 may branch off into 1×1, 1×2, 2×1, 2×2, . . . , n×n to form the input part 34 and the output part 36. A mode adaptor 38 having a width gradually decreasing in a direction of the SOA 10 may be disposed at the input part 34. Although not shown, the mode adaptor 38 may be disposed at a portion, which connects the output part 36 to the OM 20.

The MMI coupler 30 may share the second active layer 22 with the OM 20 and integrated with each other through following processes. For example, the second active layer 22 of the MMI coupler 30 and the OM 20, which are disposed on the second substrate 24 are patterned to form the clad layer 40 on an entire surface of the second substrate 24 including the second active layer 22. The second electrode 26 disposed on the clad layer 40 of the OM 20 is patterned, and the clad layer 40 and the second substrate 24 disposed on both sides of the second electrode 26 and the second active layer 22 are removed to expose the sidewall of the second active layer 22. As a result, the MMI coupler 30 may share the second active layer 22 with the OM 20, and also integrally formed with each other through one etch process in which the clad layer 40 and the second substrate 24 are removed.

Thus, in the optical device module according to an embodiment of the present invention, the OM 20 and the MMI coupler 30 are integrally formed to improve the integration of the optical device. At this time, the output part 36 of the MMI coupler 30 may have the same width as the second active layer 22 of the OM 20.

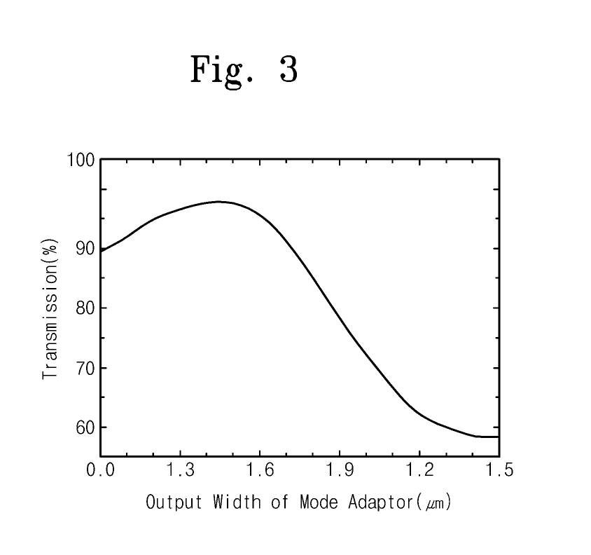

Also, the second active layer 22 of the input part 34 of the MMI coupler 30 may be junctioned to the first active layer 12 of the SOA 10 with the same linewidth. As described above, the MMI coupler 30 may include the mode adaptor 38 to reduce optical loss. For example, when the input part of the MMI coupler 30 has a width of about 1 μm, the interference part 32 may have a width of about 4 μm and a length of about 42 μm. As shown in FIG. 3, when the mode adaptor 38 having a width of about 1.45 μm is coupled to the interference part 32, the optical transmission may be maximized. The mode adaptor 38 may have a length of about 10 μm. Here, a horizontal axis of FIG. 3 represents a variation of the width of the mode adaptor 38, and the vertical axis represents the optical transmission.

Alternatively, the OM 20 and the SOA 10 may be connected to a single mode adaptor 38 without providing the MMI coupler 30. At this time, the mode adaptor 38 should have a length greater than that of the MMI coupler 30. When SOA 10 and the OM 20 respectively have lengths of about 1 μm and about 3 μm, the mode adaptor 38 for connecting the SOA 10 to the OM 20 should have a length of about 120 μm that is significantly longer that that of the MMI coupler 30.

Thus, in the optical device module according to an embodiment of the present invention, the OM 20 and the MMI coupler 30 may be integrated with each other. Also, the SOA 10 may be junctioned to the MMI coupler 30 to realize the miniaturization of the optical device.

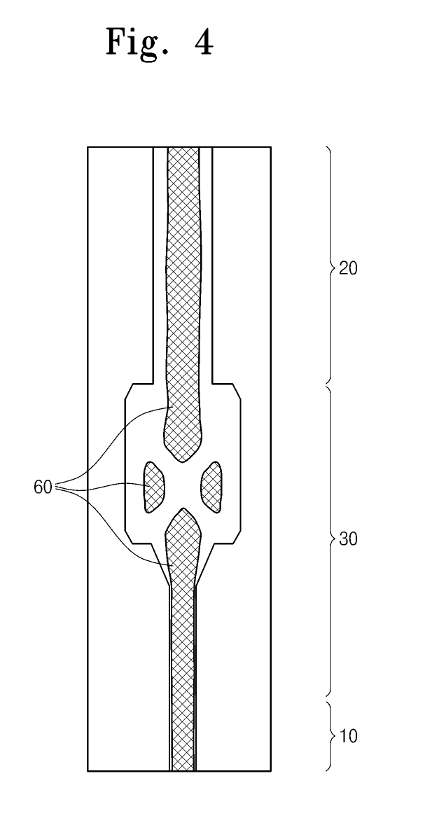

FIG. 4 is a view illustrating a result obtained by calculating an intensity of an optical signal passing through an optical device module according to an embodiment of the present invention. It is seen that light 60 transmitted from the SOA 10 passes through the MMI coupler 30 and is stably transmitted into the OM 20 to reduce an optical loss. Here, the light passing through the MMI coupler 30 may interfere and be divided into both sides, and then the divided light may be added again to each other to proceed into the OM 20.

Thus, in the optical device module according to an embodiment of the present invention, the MMI coupler 30 integrated with the OM 20 may be junctioned to the SOA 10 to minimize the optical loss. Furthermore, the SOA 10 and the OM 20, which have three-dimensional shapes and optical control operations different from each other may be easily miniaturized and integrated.

The number of the optical devices connected to the input and output parts 34 and 36 of the MMI coupler 30 may increase according to the number of the input and output parts of the MMI coupler 30.

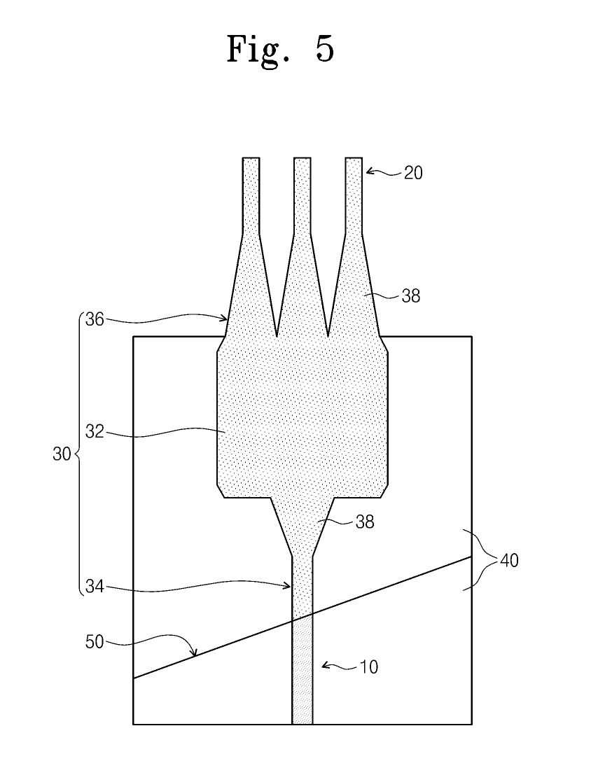

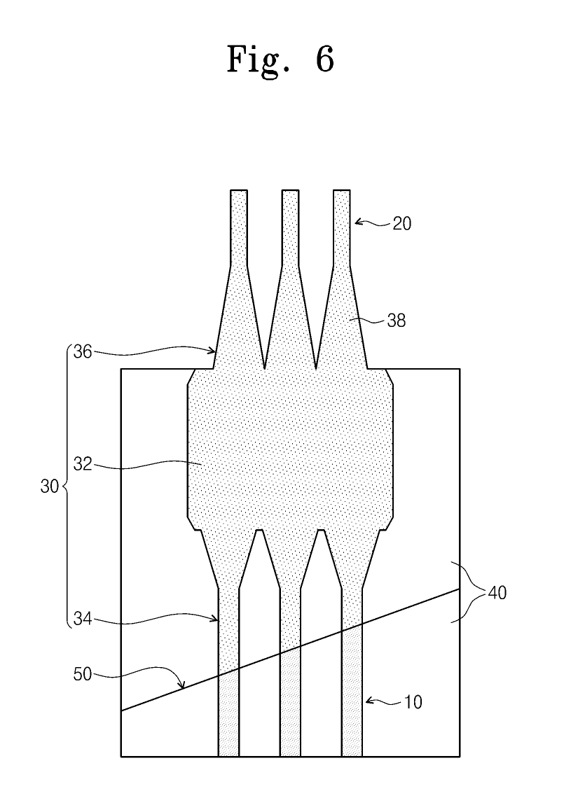

FIGS. 5 and 6 are plan views of an optical device module according to another embodiment of the present invention. An MMI coupler 30 may have share a second active layer 22 with plural OMs 20 and be integrated with the plural OMs 20. Also, the MMI coupler 30 may be junctioned to at least one or more SOAs 10. Here, the MMI coupler 30 may include one interference part 32 and be formed into a 1×3 or 3×3 type according to the number of input and output parts 34 and 36. Also, a mode adaptor 38 may be disposed at the input and output parts 34 and 36 of the MMI coupler 30.

Thus, in the optical device module according to another embodiment of the present invention, the MMI coupler 30 may be integrated to share one active layer of the plurality of optical devices to which the active layers having structures different from each other are junctioned and have a shape similar to the other optical device to improve miniaturization and integration of the device.

According to the embodiments of the present invention, the MMI coupler having the buried structure and integrated with the OM having the ridge structure may be used to easily realize the integration.

Also, the SOA having the buried structure and the OM having the ridge structure may be easily junctioned to each other.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An optical device module comprising:
a first substrate;
at least one first optical device in which a first active layer through which light passes is buried in a clad layer on the first substrate;
a second substrate junctioned to the first substrate comprising the first optical device;
at least one second optical device in which a sidewall of a second active layer disposed on the second substrate is exposed from the clad layer; and
a multi-mode interference coupler comprising the second active layer disposed on the second substrate between the second optical device and the first optical device,
wherein the multi-mode interference coupler is junctioned to the first optical device and integrated with the second optical device and buried in the clad layer.

2. The optical device module of claim 1, wherein the multi-mode interference coupler comprises at least one input part in which the second active layer having a first width equal to that of the first active layer is junctioned to the first active layer, an interference part connected to the input part and having a second width greater than that of the first width, and at least one output part connected to the interference part facing the input part and having a third width less than that of the second width.

3. The optical device module of claim 2, wherein the multi-mode interference coupler comprises at least one mode adaptor disposed at the input part or the output part.

4. The optical device module of claim 2, wherein the first width of the input part is less than the third width of the output part.

5. The optical device module of claim 4, wherein the second optical device comprises an optical modulator comprising the second active layer having the third width and a second electrode disposed on an upper portion of the clad layer on the second active layer.

6. The optical device module of claim 5, wherein sidewalls of the second active layer and the clad layer of the optical modulator are passivated with polyimide.

7. The optical device module of claim 4, wherein the second optical device has a deep ridge structure or a deep ridge that is passivated with polyimide.

8. The optical device module of claim 4, wherein the first optical device comprises a semiconductor optical amplifier comprising the first active layer having the first width, current blocking layers disposed on both sides of the first active layer, and a first electrode having a fourth width greater than the first width.

9. The optical device module of claim 7, wherein the semiconductor optical amplifier has a planar buried heterostructure or a buried ridge structure.

10. The optical device module of claim 1, wherein the first active layer of the first optical device and the second active layer of the multi-mode interference coupler are butt-jointed to each other.
